(19) United States
(12) Patent Application Publication
(10) Pub. No.: US 2025/0317113 A1
(43) Pub. Date: Oct. 9, 2025

(54) TRANSISTOR ARRAY LOCAL HEATING SENSING

(71) Applicant: SKYWORKS SOLUTIONS, INC., Irvine, CA (US)

(72) Inventor: Anatoli Pukhovski, Andover, MA (US)

(21) Appl. No.: 19/174,442

(22) Filed: Apr. 9, 2025

Related U.S. Application Data
(60) Provisional application No. 63/631,811, filed on Apr. 9, 2024.

(51) Int. Cl. H03F 3/24; H03F 1/30

(52) U.S. Cl. CPC H03F 3/245; H03F 1/30; H03F 2200/468

(57) ABSTRACT

A power amplification system comprises a power amplifier configured to receive an input signal and provide an amplified signal, a first temperature sensor disposed adjacent to a first portion of the power amplifier and configured to output a first voltage indicative of temperature at the first portion, a second temperature sensor disposed adjacent to a second portion of the power amplifier and configured to output a second voltage indicative of temperature at the second portion, a comparator configured to determine a difference between the first voltage and the second voltage, and a bias circuit configured to adjust bias current at the power amplifier based at least in part on the determined difference between the first voltage and the second voltage.

### CROSS-REFERENCE TO RELATED APPLICATION(S)

This application claims priority to U.S. Provisional Application No. 63/631,811 filed Apr. 9, 2024, entitled TRANSISTOR ARRAY LOCAL HEATING SENSING, the disclosure of which is hereby expressly incorporated by reference herein in its entirety.

### BACKGROUND

### Field

The present disclosure relates to Power Amplifiers (PAs) and related devices and methods.

### Description of the Related Art

Wireless Local Area Network (WLAN) PAs and/or Front-End Modules (FEMs) may be designed to survive harsh operational conditions. Harsh operational conditions can include operating at high power while output of the PA is mismatched. In such cases, an output stage of a PA may operates with a collector voltage exceeding breakdown voltage or a collector current density exceeding a maximum value. As a result, an output bipolar junction transistor (BJT) device of the PA and/or a part of an output device (e.g., where the PA comprises a combination of unit cells) may be damaged.

### SUMMARY

In accordance with a number of implementations, the present disclosure relates to a power amplification system including a power amplifier configured to receive an input signal and provide an amplified signal; a first temperature sensor disposed adjacent to a first portion of the power amplifier and configured to output a first voltage indicative of temperature at the first portion; a second temperature sensor disposed adjacent to a second portion of the power amplifier and configured to output a second voltage indicative of temperature at the second portion; a comparator configured to determine a difference between the first voltage and the second voltage; and a bias circuit configured to adjust bias current at the power amplifier based at least in part on the determined difference between the first voltage and the second voltage.

In some aspects, the power amplifier includes an array of four or more devices. The first temperature sensor may be disposed between a first set of two devices of the four or more devices.

The second temperature sensor may be disposed between a second set of two devices of the four or more devices. In some embodiments, the power amplifier includes a first array and a second array.

In some embodiments, the first temperature sensor and the second temperature sensor are disposed adjacent to the first array to sense temperature at the first array and not adjacent to the second array to not sense temperature at the second array. The bias circuit may be configured to reduce bias current at the first array and at the second array in response to the determined difference at the first array.

The bias circuit may be configured to reduce bias current at the power amplifier in response to the determined difference being above a threshold amount. In some examples, the bias circuit is configured to reduce bias current at each device of a stage of the power amplifier.

In some embodiments, the bias circuit is configured to activate a latch circuit to disconnect at least a portion of the power amplifier from bias current. The bias circuit may be configured to reduce bias current until an end of a packet and increase bias current after the end of the packet.

In accordance with one or more implementations, the present disclosure relates to a method for operating a power amplification system, the method including: providing an input signal to a power amplifier; amplifying the input signal with the power amplifier to generate an amplified signal; measuring a first temperature at a first portion of the power amplifier; measuring a second temperature at a second portion of the power amplifier; and generating a control signal based on the measured first temperature and the measured second temperature for adjusting a bias current associated with the power amplifier.

In some embodiments, the method further includes activating a latch circuit based on the measured first temperature and second temperature to disconnect at least a portion of the power amplifier from bias current. The method may further include resetting the latch circuit to connect the power amplifier to bias current at an end of a packet.

In some implementations, the present disclosure relates to a wireless system including a baseband sub-system configured to process a digital signal to be transmitted; a power amplifier configured to receive an analog signal representative of the digital signal and provide an amplified signal; a first temperature sensor disposed adjacent to a first portion of the power amplifier and configured to output a first voltage indicative of temperature at the first portion; a second temperature sensor disposed adjacent to a second portion of the power amplifier and configured to output a second voltage indicative of temperature at the second portion; a comparator configured to determine a difference between the first voltage and the second voltage; and a bias circuit configured to adjust bias current at the power amplifier based at least in part on the determined difference between the first voltage and the second voltage.

In some embodiments, the first temperature sensor is disposed between a first set of two devices of the power amplifier and the second temperature sensor is disposed between a second set of two devices of the power amplifier. The first temperature sensor and the second temperature sensor may be disposed adjacent to a first array of the power amplifier to sense temperature at the first array and not adjacent to a second array of power amplifier to not sense temperature at the second array.

The bias circuit may be configured to reduce bias current at the first array and at the second array in response to the determined difference at the first array. In some embodiments, the bias circuit is configured to activate a latch circuit to disconnect at least a portion of the power amplifier from bias current.

In some embodiments, the bias circuit is configured to reduce bias current until an end of a packet and increase bias current after the end of the packet.

### BRIEF DESCRIPTION OF THE DRAWINGS

FIG. 1 illustrates an example system comprising a first array and/or a second array in accordance with one or more examples.

FIG. 2 illustrates an example temperature monitoring and/or measuring system for a power amplifier (PA), in accordance with one or more examples.

FIG. 3 provides an example graph illustrating changing voltage values over time in accordance with one or more examples.

FIG. 4 provides another example graph illustrating changing voltage values over time in accordance with one or more examples.

FIG. 5 illustrates an RF module having a packaging substrate that can include die mounted thereon and having a power amplification system.

FIG. 6 illustrates an RF module having a packaging substrate that can include a first die having a power amplifier implemented thereon, a second die having a monitor circuit implemented thereon, and a third die having a Digital Pre-Distortion (DPD) system implemented thereon.

FIG. 7 illustrates an RF module having a packaging substrate that can include a first die having a power amplifier implemented thereon, and a second die having a monitor circuit implemented thereon.

FIG. 8 illustrates a wireless system shown to further include a power source configured to power some or all of the various parts of the wireless system.

### DETAILED DESCRIPTION OF SOME EMBODIMENTS

The headings provided herein, if any, are for convenience only and do not necessarily affect the scope or meaning of the claimed invention.

Wireless Local Area Network (WLAN) Power Amplifiers (PAs) and/or Front-End Modules (FEMs) may be designed to survive harsh operational conditions. Harsh operational conditions can include operating at high power while output of the PA is mismatched. In such cases, an output stage of a PA may operates with a collector voltage exceeding breakdown voltage or a collector current density exceeding a maximum value. As a result, an output bipolar junction transistor (BJT) device of the PA and/or a part of an output device (e.g., where the PA comprises a combination of unit cells) may be damaged.

In some cases, damage to the PA may occur when the output stage of the PA is overheated and enters a state known as “thermal runaway” and/or burns out. The PA may be damaged and/or characteristics of the performance may be degraded, hence reducing radio and/or other performance.

One option for preventing damage to a PA involves monitoring output voltage and/or reducing bias current of the PA's output stage with a feedback signal. Additionally, or alternatively, the input power to the PA may be monitored and/or gain at the PA may be reduced when input power exceeds certain input power. In this way, a third stage and/or output stage of the PA may not experience excessive power. In some cases, capacitance of ballast resistors of the PA may be increased to prevent transistor thermal runaway. Additionally, or alternatively, bias current may be reduced when the bias current rises above a certain level. In some examples, RF power may be detected in a bias portion of the PA and/or the bias current may be reduced proportionally.

Some PAs may experience overheating, particularly at an output array and/or output transistor of the PA. In some cases, devices (e.g., transistors) at some portions of an array can overheat more than devices at other portions of an array. For example, devices located at middle portions of an array may not be able to dissipate heat as well as devices at edge portions of the array.

Accordingly, it may be advantageous to utilize one or more temperature sensors configured to sense temperature at or near one or more devices of an array. The temperature sensors may be configured to monitor devices at one portion of an array (e.g., a middle portion of the array) and/or at multiple portions (e.g., at a middle portion and/or at one or more edge portions). The temperature sensors can comprise one or more diodes and/or diode-connected transistors. In some examples, the one or more temperature sensors may be configured to monitor temperature at one or more devices and/or generate one or more signals in response to changes in temperature. For example, if temperature at a device exceeds a threshold temperature value, the one or more sensors may be configured to generate a signal indicating the device(s) and/or array may be entering a thermal runaway.

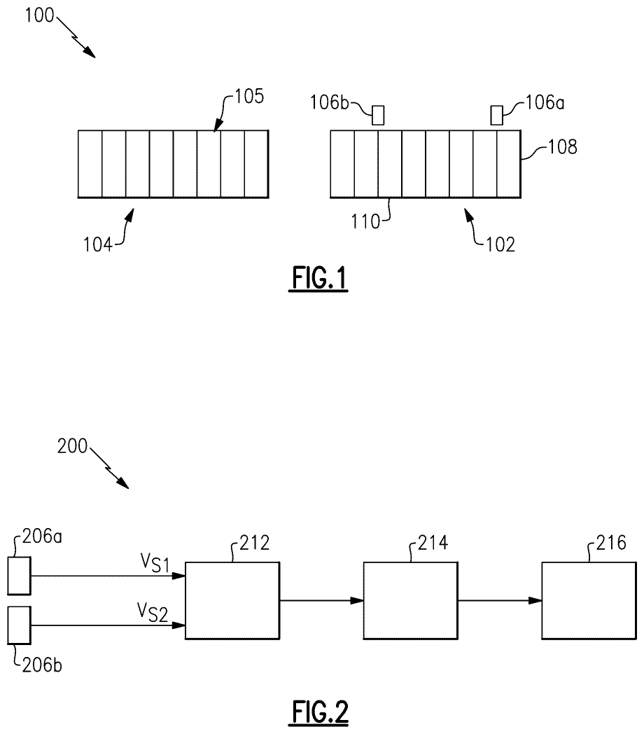

FIG. 1 illustrates an example system 100 comprising a first array 102 and/or a second array 104 in accordance with one or more examples. The system 100 may comprise one or more temperature sensors 106 configured to monitor temperature at the first array 102. While the system 100 is shown comprising two sensors 106 including a first sensor 106a and a second sensor 106b, the system 100 can comprise any number of sensors 106. The first array 102 and the second array 104 may be separate arrays and/or may be connected in parallel.

The sensor(s) 106 may be configured to monitor temperature at one or more portions of the first array 102 and/or second array 104. The first array 102 and/or second array 104 can comprise one or more devices 105, which can include transistors and/or other components. In some examples, the first sensor 106a and/or the second sensor 106b may each be disposed between two devices 105 of the first array 102.

In response to at least one part of the first array 102 becoming hot and/or hotter than another portion of the first array 102, the sensor(s) 106 may be configured to generate a signal indicating a potential thermal runaway. In some examples, the system 100 may comprise a sensing circuit configured to receive signals from the sensor(s) 106 and/or configured to reduce bias current at the first array 102, the second array 104, and/or system 100.

The first array 102 and/or second array 104 may be biased from a common bias block. Thus, in the event of overheating, bias at the first array 102 and/or second array 104 may be reduced. For example, an entire stage of a power amplifier may be powered down. When bias at one part of the system 100 (e.g., the first array 102) is reduced, a second part of the system 100 (e.g., the second array 104) may handle increased amplification and/or may carry increased current, which may cause damage to the second part of the system 100. It may therefore be advantageous to reduce bias across an entire stage of power amplifier.

Different portions and/or areas of an array may heat up at different rates and/or by different amounts. For example, devices 105 disposed at a middle portion 110 of the first array 102 may heat up to a greater degree than devices 105 disposed at an edge portion 108 of the first array 102 due to the devices 105 in the middle portion 110 being disposed between other devices 105 of the first array 102. Heating at the devices 105 may cause additional heating at other devices 105. In contrast, heat at devices 105 at the edge portion(s) 108 may be more easily dissipated.

In some examples, the first sensor 106a and the second sensor 106b may be positioned and/or disposed at or near different portions of the first array 102. For example, the first sensor 106a may be disposed at or near an edge portion 108 of the first array 102 and/or the second sensor 106b may be disposed at or near a middle portion 110 (e.g., central portion) of the first array 102.

The system 100 may be configured to sense temperature differences between the first sensor 106a and/or the second sensor 106b. For example, temperature data from the first sensor 106a (e.g., at or near the edge portion 108) may be compared to temperature data from the second sensor 106b (e.g., at or near the middle portion 110) by a control/sensing circuit. In some examples, temperature sensing and/or comparison may be performed in real time. For example, sensed temperature may be relayed to a control circuit via one or more signals and/or the control circuit may be configured to reduce bias current immediately in response to detecting a potential thermal runaway at the first array 102. Additionally, or alternatively, the system 100 may comprise a latch circuit configured to protect the first array 102 and/or one or more devices 105 of the first array 102 and/or system 100 until an end of a transmission packet and/or other event. For example, a control circuit may be configured to activate a latch circuit in response to detecting a potential thermal runaway. The latch circuit may be configured to disconnect at least a portion of the system 100 (e.g., the first array 102) from bias current. The latch circuit can comprise a Schmitt trigger and/or similar device and/or may be configured to shut down current to one or more stages of the system 100 until the end of the packet. At the end of the packet, the latch circuit may be configured to switch from a transmit mode to a receive mode and/or a latch may be reset. In some examples, bias current to only one stage (e.g., an output stage) may be reduced and/or power available to one or more stages may be reduced in response to detection of overheating.

Some methods of protecting against overheating can rely on sensing signals at an input and/or output of a PA. However, an increase of voltage and/or power at the input and/or output of the PA may not necessarily indicate that one or more devices of the PA are experiencing stress. Some PA circuits can operate and/or trigger the PA to enter a “safe” mode of operation, wherein the PA has reduced bias. The PA systems described herein can advantageously measure and/or monitor temperature directly at devices in one or more transistor arrays that can become overstressed. In this way, the systems described herein can effectively protect the PA when overstress occurs.

FIG. 2 illustrates an example temperature monitoring and/or measuring system 200 for a PA, in accordance with one or more examples. The system 200 may comprise a first temperature sensor 206a and/or a second temperature sensor 206b configured to measure temperature values at one or more arrays (e.g., of a device 216) of a PA. The first temperature sensor 206a and/or second temperature sensor 206b may comprise one or more diodes and/or diode-connected transistors.

In some examples, the first temperature sensor 206a and/or second temperature sensor 206b may be configured to indicate temperature levels via voltage values. For example, the first temperature sensor 206a may be configured to output a first voltage (e.g., a first source voltage) and/or the second temperature sensor 206b may be configured to output a second voltage (e.g., a second source voltage). The first voltage and/or the second voltage may be indicative of temperature levels at one or more devices of an array of the PA. For example, the first voltage may indicate a temperature at a first device located at an edge region of the PA and/or the second voltage may indicate a temperature at a second device located at a middle and/or central region of the PA.

The system 200 may comprise a comparator 212 and/or comparison circuit configured to receive the first voltage and/or second voltage from the first temperature sensor 206a and/or second temperature sensor 206b. The comparator 212 may comprise any suitable components (e.g., circuit components) configured to compare voltages and/or currents output by the first temperature sensor 206a and/or second temperature sensor 206b. In some examples, the comparator 212 may be configured to compare the first voltage to the second voltage. However, the comparator 212 may additionally or alternatively compare the first voltage and/or the second voltage to a threshold voltage.

The comparator 212 may be configured to output an output voltage and/or output current to a bias circuit 214. The bias circuit 214 may comprise any suitable components configured to generate and/or output a bias voltage and/or bias current. The bias circuit 214 may be configured to output a bias voltage and/or bias current that is based on the output from the comparator 212. For example, in response to the comparator 212 determining that a temperature value at a PA array and/or that a voltage received from the first temperature sensor 206a and/or second temperature sensor 206b exceeds a desired value, the comparator 212 output a voltage and/or current indicative of a potential thermal runaway. The bias circuit 214 may be configured to reduce bias voltage and/or current in response to detection of a potential thermal runaway at the comparator 212. The bias circuit 214 may be configured to adjust bias voltage and/or current levels and/or output adjusted bias voltages and/or current to one or more devices 216 (e.g., radio-frequency (RF) BJTs and/or other transistors) and/or arrays of a PA. The adjusted (e.g., reduced) bias voltages and/or currents may reduce temperature at the one or more devices 216 and/or prevent overheating.

FIG. 3 provides an example graph 300 illustrating changing voltage values over time in accordance with one or more examples. The graph 300 may illustrate normal operation of an example system described herein where overheating may not be occurring. A first voltage 322 may be outputted by a first temperature sensor disposed at or near a first device of a PA. A second voltage 324 may be outputted by a second temperature sensor disposed at or near a second device of the PA. The first voltage 322 and/or the second voltage 324 may increase and/or decrease gradually and/or in synchronization with each other during normal operation.

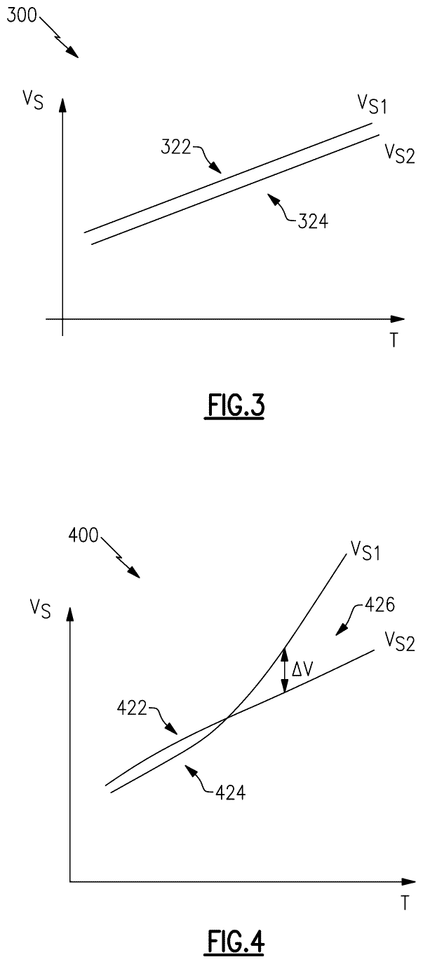

FIG. 4 provides another example graph 400 illustrating changing voltage values over time in accordance with one or more examples. The graph 400 may illustrate operation under stress of an example system described herein and/or where overheating may be occurring. A first voltage 422 may be outputted by a first temperature sensor disposed at or near a first device of a PA. A second voltage 424 may be outputted by a second temperature sensor disposed at or near a second device of the PA.

The first device and/or a first area of the PA may overheat relative to the second device and/or second area of the PA. Accordingly, the first voltage 422 and/or second voltage 424 may change at different rates based at least in part on different temperatures sensed at the different devices. As the first voltage 422 and the second voltage 424 increase and/or decrease at different rates, a voltage difference 426 between the first voltage 422 and the second voltage 424 may increase. A comparator of a system may be configured to determine the voltage difference 426 and/or to compare the voltage difference 426 to a threshold value. When the voltage difference 426 increases beyond the threshold value, the comparator may be configured to transmit a signal (e.g., output voltage) to a bias circuit and/or bias block. The bias circuit may be configured to reduce bias current and/or bias voltage in response to the signal from the comparator.

### Examples of System Implementations:

FIG. 5 shows that in some embodiments, an RF module 520 having a packaging substrate 522 can include die 510 mounted thereon and having a power amplification system 500. Such a power amplification system can include a power amplifier 602 and a monitor and adapt system 809 having one or more features as described herein.

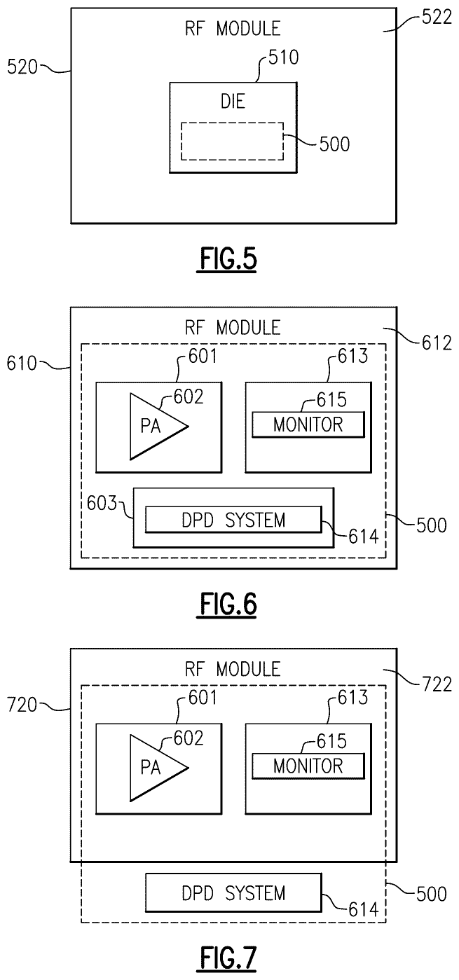

FIG. 6 shows that in some embodiments, an RF module 610 having a packaging substrate 612 can include a first die 601 having a power amplifier 602 implemented thereon, a second die 613 having a monitor circuit 615 implemented thereon, and a third die 603 having a Digital Pre-Distortion (DPD) system 614 implemented thereon. In such a configuration, the RF module 610 can include substantially all of a power amplification system 500 implemented on a plurality of die.

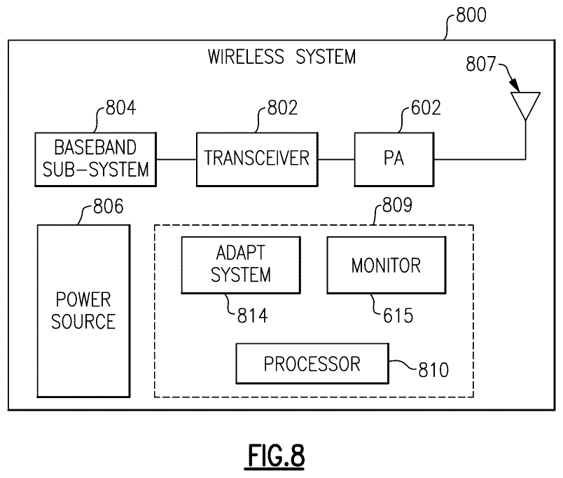

FIG. 7 shows that in some embodiments, an RF module 720 having a packaging substrate 722 can include a first die 601 having a power amplifier 602 implemented thereon, and a second die 613 having a monitor circuit 615 implemented thereon. A DPD system 614 is shown to be implemented outside of the RF module 720. In such a configuration, the RF module 720 can include a portion of a power amplification system 500 implemented on one or more die (e.g., the PA 602 and the monitor circuit 615), and the other portion (e.g., the DPD system 614) of the amplification system 500 can be implemented away from the RF module 720.

FIG. 8 shows a block diagram of a wireless system 800 that includes a power amplification system having one or more features as described herein. The power amplification system can include a power amplifier 602, and such a power amplifier can be in communication with a transceiver 802 and receive from the transceiver 802 an RF signal to be amplified and transmitted through an antenna 807. The transceiver 802 can be in communication with a baseband sub-system 804 that is configured to process digital signals. In some embodiments, the baseband sub-system 804 can include at least a portion of a DPD system having one or more features as described herein, and such a DPD system can be a part of the power amplification system.

In the example of FIG. 8, a monitor and adapt system 809 having one or more features as described herein can be a part of the foregoing power amplification system. The monitor and adapt system 809 can include a monitor system 615 and an adapt system 814. In some embodiments, the monitor and adapt system 809 can also include a processor 810 configured to support either or both of the monitor system 615 and the adapt system 814.

In the example of FIG. 8, the wireless system 800 is shown to further include a power source 806 configured to power some or all of the various parts of the wireless system 800.

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged and certain steps and/or phases may be omitted entirely. Also, the methods described herein are to be understood to be open-ended, such that additional steps and/or phases to those shown and described herein can also be performed.

Some aspects of the systems and methods described herein can advantageously be implemented using, for example, computer software, hardware, firmware, or any combination of computer software, hardware, and firmware. Computer software can comprise computer executable code stored in a computer readable medium (e.g., non-transitory computer readable medium) that, when executed, performs the functions described herein. In some embodiments, computer-executable code is executed by one or more general purpose computer processors. A skilled artisan will appreciate, in light of this disclosure, that any feature or function that can be implemented using software to be executed on a general-purpose computer can also be implemented using a different combination of hardware, software, or firmware. For example, such a module can be implemented completely in hardware using a combination of integrated circuits. Alternatively, or additionally, such a feature or function can be implemented completely or partially using specialized computers designed to perform the particular functions described herein rather than by general purpose computers.

Multiple distributed computing devices can be substituted for any one computing device described herein. In such distributed embodiments, the functions of the one computing device are distributed (e.g., over a network) such that some functions are performed on each of the distributed computing devices.

Some embodiments may be described with reference to equations, algorithms, and/or flowchart illustrations. These methods may be implemented using computer program instructions executable on one or more computers. These methods may also be implemented as computer program products either separately, or as a component of an apparatus or system. In this regard, each equation, algorithm, block, or step of a flowchart, and combinations thereof, may be implemented by hardware, firmware, and/or software including one or more computer program instructions embodied in computer-readable program code logic. As will be appreciated, any such computer program instructions may be loaded onto one or more computers, including without limitation a general-purpose computer or special purpose computer, or other programmable processing apparatus to produce a machine, such that the computer program instructions which execute on the computer(s) or other programmable processing device(s) implement the functions specified in the equations, algorithms, and/or flowcharts. It will also be understood that each equation, algorithm, and/or block in flowchart illustrations, and combinations thereof, may be implemented by special purpose hardware-based computer systems which perform the specified functions or steps, or combinations of special purpose hardware and computer-readable program code logic means.

Furthermore, computer program instructions, such as embodied in computer-readable program code logic, may also be stored in a computer readable memory (e.g., a non-transitory computer readable medium) that can direct one or more computers or other programmable processing devices to function in a particular manner, such that the instructions stored in the computer-readable memory implement the function(s) specified in the block(s) of the flowchart(s). The computer program instructions may also be loaded onto one or more computers or other programmable computing devices to cause a series of operational steps to be performed on the one or more computers or other programmable computing devices to produce a computer-implemented process such that the instructions which execute on the computer or other programmable processing apparatus provide steps for implementing the functions specified in the equation(s), algorithm(s), and/or block(s) of the flowchart(s).

Some or all of the methods and tasks described herein may be performed and fully automated by a computer system. The computer system may, in some cases, include multiple distinct computers or computing devices (e.g., physical servers, workstations, storage arrays, etc.) that communicate and interoperate over a network to perform the described functions. Each such computing device typically includes a processor (or multiple processors) that executes program instructions or modules stored in a memory or other non-transitory computer-readable storage medium or device. The various functions disclosed herein may be embodied in such program instructions, although some or all of the disclosed functions may alternatively be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid-state memory chips and/or magnetic disks, into a different state.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list. The word “exemplary” is used exclusively herein to mean “serving as an example, instance, or illustration.” Any implementation described herein as “exemplary” is not necessarily to be construed as preferred or advantageous over other implementations.

The disclosure is not intended to be limited to the implementations shown herein. Various modifications to the implementations described in this disclosure may be readily apparent to those skilled in the art, and the generic principles defined herein may be applied to other implementations without departing from the spirit or scope of this disclosure. The teachings of the invention provided herein can be applied to other methods and systems and are not limited to the methods and systems described above, and elements and acts of the various embodiments described above can be combined to provide further embodiments. Accordingly, the novel methods and systems described herein may be embodied in a variety of other forms; furthermore, various omissions, substitutions, and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A power amplification system comprising:
a power amplifier configured to receive an input signal and provide an amplified signal;
a first temperature sensor disposed adjacent to a first portion of the power amplifier and configured to output a first voltage indicative of temperature at the first portion;
a second temperature sensor disposed adjacent to a second portion of the power amplifier and configured to output a second voltage indicative of temperature at the second portion;
a comparator configured to determine a difference between the first voltage and the second voltage; and
a bias circuit configured to adjust bias current at the power amplifier based at least in part on the determined difference between the first voltage and the second voltage.

2. The power amplification system of claim 1 wherein the power amplifier comprises an array of four or more devices.

3. The power amplification system of claim 2 wherein the first temperature sensor is disposed between a first set of two devices of the four or more devices.

4. The power amplification system of claim 3 wherein the second temperature sensor is disposed between a second set of two devices of the four or more devices.

5. The power amplification system of claim 1 wherein the power amplifier comprises a first array and a second array.

6. The power amplification system of claim 5 wherein the first temperature sensor and the second temperature sensor are disposed adjacent to the first array to sense temperature at the first array and not adjacent to the second array to not sense temperature at the second array.

7. The power amplification system of claim 6 wherein the bias circuit is configured to reduce bias current at the first array and at the second array in response to the determined difference at the first array.

8. The power amplification system of claim 1 wherein the bias circuit is configured to reduce bias current at the power amplifier in response to the determined difference being above a threshold amount.

9. The power amplification system of claim 1 wherein the bias circuit is configured to reduce bias current at each device of a stage of the power amplifier.

10. The power amplification system of claim 1 wherein the bias circuit is configured to activate a latch circuit to disconnect at least a portion of the power amplifier from bias current.

11. The power amplification system of claim 1 wherein the bias circuit is configured to reduce bias current until an end of a packet and increase bias current after the end of the packet.

12. A method for operating a power amplification system, the method comprising:
providing an input signal to a power amplifier;
amplifying the input signal with the power amplifier to generate an amplified signal;
measuring a first temperature at a first portion of the power amplifier;
measuring a second temperature at a second portion of the power amplifier; and
generating a control signal based on the measured first temperature and the measured second temperature for adjusting a bias current associated with the power amplifier.

13. The method of claim 12 further comprising activating a latch circuit based on the measured first temperature and second temperature to disconnect at least a portion of the power amplifier from bias current.

14. The method of claim 13 further comprising resetting the latch circuit to connect the power amplifier to bias current at an end of a packet.

15. A wireless system comprising:
a baseband sub-system configured to process a digital signal to be transmitted;
a power amplifier configured to receive an analog signal representative of the digital signal and provide an amplified signal;
a first temperature sensor disposed adjacent to a first portion of the power amplifier and configured to output a first voltage indicative of temperature at the first portion;
a second temperature sensor disposed adjacent to a second portion of the power amplifier and configured to output a second voltage indicative of temperature at the second portion;
a comparator configured to determine a difference between the first voltage and the second voltage; and
a bias circuit configured to adjust bias current at the power amplifier based at least in part on the determined difference between the first voltage and the second voltage.

16. The wireless system of claim 15 wherein the first temperature sensor is disposed between a first set of two devices of the power amplifier and the second temperature sensor is disposed between a second set of two devices of the power amplifier.

17. The wireless system of claim 16 wherein the first temperature sensor and the second temperature sensor are disposed adjacent to a first array of the power amplifier to sense temperature at the first array and not adjacent to a second array of power amplifier to not sense temperature at the second array.

18. The wireless system of claim 17 wherein the bias circuit is configured to reduce bias current at the first array and at the second array in response to the determined difference at the first array.

19. The wireless system of claim 15 wherein the bias circuit is configured to activate a latch circuit to disconnect at least a portion of the power amplifier from bias current.

20. The wireless system of claim 15 wherein the bias circuit is configured to reduce bias current until an end of a packet and increase bias current after the end of the packet.
